(19) United States
(12) Patent Application Publication
(10) Pub. No.: US 2018/0287001 A1
(43) Pub. Date: Oct. 4, 2018

(54) HIGH VOLTAGE PHOTOVOLTAICS WITH STACKED MULTI-JUNCTIONS USING WIDE BANDGAP MATERIALS

(71) Applicant: INTERNATIONAL BUSINESS MACHINES CORPORATION, Armonk, NY (US)

(72) Inventors: Stephen W. Bedell, Wappingers Falls, NY (US); Ning Li, White Plains, NY (US); Devendra K. Sadana, Pleasantville, NY (US); Ghavam G. Shahidi, Pound Ridge, NY (US)

(21) Appl. No.: 15/477,654

(22) Filed: Apr. 3, 2017

(51) Int. Cl. H01L 31/074; H01L 31/0735; H01L 31/0725; H01L 31/18; H01L 31/0352

(52) U.S. Cl. CPC H01L 31/074; H01L 31/0735; H01L 31/0725; H01L 31/1812; H01L 31/1864; H01L 31/1848; H01L 31/035236; H01L 31/1856

(57) ABSTRACT

A photovoltaic device including a first cell positioned at a light receiving end of the photovoltaic device. The first cell has a first sequence of first semiconductor material layers of a first composition and the first junction has a first thickness. The photovoltaic device further includes at least a second cell positioned further from the light receiving end of the photovoltaic device than the first cell. Each cell in the at least one second cell has a greater thickness than the first thickness. The at least second cell comprising second semiconductor material layers in a second sequence equal to the first semiconductor material layers in the first sequence of the first cell.

### BACKGROUND

### Technical Field

The present invention generally relates to photovoltaic devices, and more particularly to photovoltaic devices used for high voltage output.

### Description of the Related Art

A photovoltaic device is a device that converts the energy of incident photons to electromotive force (e.m.f.). Photovoltaic devices include solar cells, which are configured to convert the energy in the electromagnetic radiation from the sun to electric energy.

### SUMMARY

In accordance with one embodiment, a photovoltaic device is provided including a first cell positioned at a light receiving end of the photovoltaic device, the first cell including a first junction having a first sequence of first semiconductor material layers, the first cell having a first thickness. At least a second cell is positioned further from the light receiving end of the photovoltaic device than the first cell. Each cell for the at least one second cell has a greater thickness than the first thickness of the first cell. Each cell in the at least one second cell has a second junction with second semiconductor material layers in a second sequence that is equal to the first sequence of first semiconductor material layers in the first junction for the first cell.

In another embodiment, a method of forming a photovoltaic device is provided that includes growing a bottom cell on a supporting substrate, the bottom cell including a bottom sequence of material compositions to provide a bottom junction; and forming at least one upper cell on the bottom junction. The upper cell is formed using a deposition method that employs low hydrogen precursors. The upper cell includes an upper sequence of material compositions to provide an upper junction, in which the upper sequence of the material compositions is substantially a same sequence of composition material layers as the bottom sequence of material compositions. The upper cell has a lesser thickness than the bottom cell, and the upper cell is positioned at the light receiving end of the photovoltaic device.

In another aspect, a method of using a photovoltaic device is described herein. In some embodiments, the method includes providing a material stack having at least two photovoltaic cells, wherein a composition for a junction for each photovoltaic cell is the same, and a thickness for each photovoltaic cell in the material stack of at least two photovoltaic cells decreases with increasing distance away from a light receiving end of the photovoltaic device. The method includes applying a single wavelength light to the photovoltaic device. A first portion of the single wavelength light is absorbed by a first cell of the at least two photovoltaic cells at the light receiving end, and at least a portion of a remaining single wavelength light is absorbed by at least a second cell of the at least two photovoltaic cells.

### BRIEF DESCRIPTION OF THE DRAWINGS

The following description will provide details of preferred embodiments with reference to the following figures wherein:

FIG. 1 is a side cross-sectional view depicting one embodiment of a high voltage photovoltaic cell including two gallium nitride (GaN) junctions, in which the first junction closest to the light receiving end of the device has a lesser thickness than the junction that is furthest from the light receiving end of the device.

FIG. 2 is a side cross-sectional view depicting one embodiment of a high voltage photovoltaic cell including two aluminum gallium nitride (AlGaN) junctions.

FIG. 3 is a side cross-sectional view depicting one embodiment of a high voltage photovoltaic cell including two aluminum nitride (AlN) junctions.

FIG. 4 is a side cross-sectional view depicting one embodiment of a high voltage photovoltaic cell including junctions of p-type aluminum gallium nitride (p-AlGaN), intrinsic gallium nitride (i-GaN) and n-type aluminum gallium nitride (n-AlGaN).

FIG. 5 is a side cross-sectional view depicting one embodiment of a high voltage photovoltaic cell including junctions of p-type gallium nitride (p-GaN), intrinsic indium gallium nitride (i-InGaN) and gallium nitride (GaN) quantum wells and n-type gallium nitride (n-GaN).

FIG. 6 is a side cross-sectional view depicting one embodiment of a high voltage photovoltaic cell including a first junction of gallium nitride and a second junction of silicon carbide.

### DETAILED DESCRIPTION

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the invention, as it is oriented in the drawing figures. The terms “overlying”, “atop”, “positioned on” or “positioned atop” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected without any intermediary conducting, insulating or semiconductor layers at the interface of the two elements.

In one embodiment, the present disclosure provides photovoltaic cells, i.e., photovoltaic devices, needed for internet of things (IOT) applications. As used herein, a “photovoltaic device” is a device, such as a solar cell, that produces free electrons and/or vacancies, i.e., holes, when exposed to radiation, such as light, and results in the production of an electric current. A multi-junction photovoltaic device may include multiple junctions of a semiconductor layer of a p-type conductivity that shares an interface with a semiconductor layer of an n-type conductivity, in which the interface provides an electrical junction. Physically small, i.e., devices having a small footprint, having high voltage requirements are needed. The length and width dimensions of the monolithically formed devices of high voltage photovoltaics integrated with LEDS that are described herein may be no greater than 150 microns, e.g, may be equal to 100 microns or less.

The photovoltaic devices that are provided herein are stacked in a material stack so that they are connected in series. Further, the photovoltaic devices that are described herein include a plurality of cells, in which each cell includes a junction that produces voltage in response to the application of light, i.e., light wavelengths. In some embodiments, each cell in the material stack has a same sequence of material composition layers. Because each cell is composed of the same sequence of material composition layers, each cell in the photovoltaic device may produce light in response to the same wavelength of light, or same range of wavelength of light. To provide for a greatest degree of absorption, the thickness of each cell decreases in a direction away from the light receiving end of the device. For example, if the material stack for the photovoltaic device included three junctions, the junction closes to the light receiving end of the device would have the least thickness, and the junction furthest from the light receiving end would have the greater thickness. The middle junction between the junction at the light receiving end and the junction furthest from the light receiving end would have a thickness greater than the thickness of the junction at the light receiving end and have a thickness lesser than the thickness of the junction furthest from the light receiving end.

Because the junctions are series connected in a material stack, i.e., formed directly atop one another, the junctions within the material stack may be referred to as being monolithically integrated. Monolithically integrated cells within a photovoltaic device can reduce size of an electrical device including the photovoltaic device. In some embodiments, the methods and structures that are described herein employ wide bandgap semiconductor materials and low hydrogen growth methods to stack multi-junctions for high voltage output arrangements. A band gap is an energy range in a solid where no electron states can exist. In graphs of the electronic band structure of solids, the band gap generally refers to the energy difference (in electron volts) between the top of the valence band and the bottom of the conduction band in insulators and semiconductors. It is the energy to promote a valence electron bound to an atom to become a conduction electron, which is free to move within the crystal lattice and serve as a charge carrier to conduct electric current.

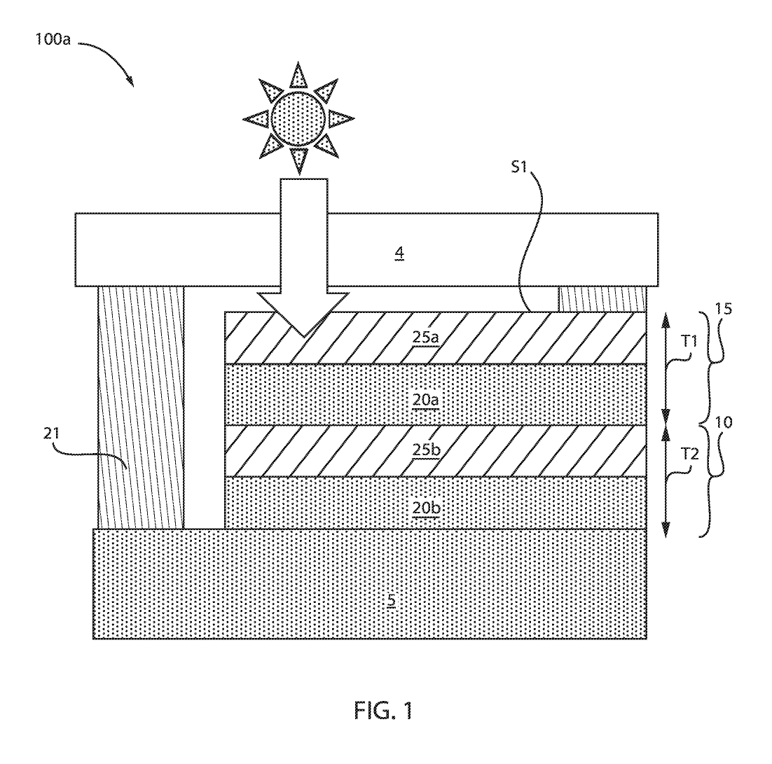

Referring to FIG. 1, a multi-junction photovoltaic device 100a is depicted that includes a plurality of cells 10, 15 that are stacked atop one another having varying thicknesses T1, T2 and the same composition materials for each cell. In some embodiment, the photovoltaic device 100a may include a first cell positioned at a light receiving end S1 of the photovoltaic device 100c. In this example, the first cell is the upper cell for the photovoltaic device, with the term “upper” corresponding to the light receiving end. The first cell, alternatively referred to as upper cell, is identified by reference number 15. The first cell 15 may include a first junction having a first sequence of first semiconductor material layers 20a, 25a. The first cell 15 has a first thickness T1. The first cell 15 being in closest proximity of the all the cells within the photovoltaic device 100a has the least thickness T1 for all the cell within the material stack for the photovoltaic device 100a.

Referring to FIG. 1, a second cell 10 is depicted at the end of the material stack that is opposite the light receiving end S1 of the material stack. In the embodiment that is depicted in FIG. 1, the second cell 10 is present on the supporting substrate 5. The second cell 10 may be interchangeably referred to as the bottom junction. In the embodiment that is depicted in FIG. 1, the second cell 10 may be in direct contact with the first cell 15, so that the first and second cells 15, 10 are in series. The second cell 10 may have a thickness T2 that is greater than the first thickness T1 of the first junction 15. In the embodiment depicted in FIG. 1, the second cell 15 includes a second junction of second semiconductor material layers 20b, 25b are present in a second sequence equal to the first sequence of first semiconductor material layers 20a, 25b in said first cell 15. Because each cell, i.e., first cell 15 and second cell 10, is composed of the same sequence of material composition layers, each cell 10, 15 in the photovoltaic device 100a may produce voltage in response to the same wavelength of light, or same range of wavelength of light. The thickness of the cells is selected to increase in a direction way from the light receiving end S1 of the device. This provides that the upper cells absorb one some of the light and produce a first voltage, and that the underlying bottom cells absorb another portion of the light and produce a second voltage, in which the first and second voltage both contribute to the total output of the device.

In the material stack depicted in FIG. 1, there are only two cells 10, 15 being depicted. It is noted that the present disclosure is not limited to only this example. The material stack may include any number of cells. In the embodiment that is depicted in FIG. 1, the material stack may include any number of cells having the same compositions material that provide the junction, e.g, n-type and p-type gallium nitride (GaN). For example, the number of cells in the material stack, i.e., number of cells including a junction, e.g., p-n junction, suitable for producing voltage in response to the application of light, may be equal to 2, 3, 4, 5, 10, 15, 20 and 25, or any range of cells having an upper level provided by one of the aforementioned examples, and a lower level provided by one of the aforementioned examples.

In the embodiment depicted in FIG. 1, the first junction, i.e., p-n junction, of the first cell 15 is provided by a first p-type gallium nitride layer 25a and a first n-type gallium nitride layer 20a that are in direct contact with one another. These materials are one embodiment of a wide band gap material. The band gap for gallium nitride (GaN) is on the order of 3.4 eV. The first cell 15 of the photovoltaic device 100a that is depicted in FIG. 1 when receiving a light wavelength ranging from 300 nm to 400 nm can provide a voltage that is greater than 2.0 eV. In yet other examples, the voltage produced by the first cell 15 of the photovoltaic device 100a is greater than 2.25 eV. For example, the photovoltaic device 100a that includes the first cell 15 including the junction of the n-type gallium nitride (GaN) layer and the p-type gallium nitride (GaN) layer that is depicted in FIG. 1 may produce a voltage of 2.5 V or greater. It is noted that the above examples are provided for illustrative purposes only, and are not intended to limit the present disclosure. In other examples, the voltage produced by the first cell 15 of the photovoltaic device 100a composed of the n-type and p-type conductivity gallium nitride (GaN) layers depicted in FIG. 1 may be equal to 2.0 V, 2.25 V, 2.5 V, 2.75 V, 3.0 V, 3.25 V, and 3.5V, as well as any value between the aforementioned examples, and any range of voltages having a lower limit provided by one of the aforementioned example voltages, and an upper limit provided by one of the aforementioned example voltages.

Each of the p-type conductivity gallium and nitride containing layer 25a, e.g., p-type gallium nitride (GaN), and the n-type conductivity gallium and nitride containing layer 20a, e.g., n-type gallium nitride (GaN) can have a thickness ranging from 100 nm to 2000 nm. In other embodiments, each of the p-type conductivity gallium and nitride containing layer 25a, e.g., p-type gallium nitride (GaN), and the n-type conductivity gallium and nitride containing layer 20a, e.g., n-type gallium nitride (GaN) can have a thickness ranging from 100 nm to 500 nm. In some embodiments, the thickness of the p-type conductivity gallium and nitride containing layer 25a and the n-type conductivity gallium and nitride containing layer 20a is selected to provide a first cell 15 having a thickness that is less than the underlying second cell 10. For example, the thickness of the p-type conductivity gallium and nitride containing layer 25a and the n-type conductivity gallium and nitride containing layer 20a may be selected to have a thickness of less than 0.5 microns, when the second sell 10 has a thickness that is 1 micron or greater.

As used herein, “p-type” refers to the addition of impurities to an intrinsic semiconductor that creates deficiencies of valence electrons. As used herein, “n-type” refers to the addition of impurities that contributes free electrons to an intrinsic semiconductor. In a type III-V semiconductor material, the effect of the dopant atom, i.e., whether it is a p-type or n-type dopant, depends upon the site occupied by the dopant atom on the lattice of the base material. In a III-V semiconductor material, atoms from group II act as acceptors, i.e., p-type, when occupying the site of a group III atom, while atoms in group VI act as donors, i.e., n-type, when they replace atoms from group V. Dopant atoms from group IV, such a silicon (Si), have the property that they can act as acceptors or donor depending on whether they occupy the site of group III or group V atoms respectively. Such impurities are known as amphoteric impurities. The dopant that provides the n-type conductivity for the n-type conductivity gallium and nitride containing layer 20a may be present in a concentration ranging from 10¹⁷ atoms/cm³ to 10²⁰ atoms/cm³. The dopant that provides the p-type conductivity of the p-type conductivity gallium and nitride containing layer 25a may be present in a concentration ranging from 10¹⁷ atoms/cm³ to 10²⁰ atoms/cm³. The second junction for the second cell 10 is in direct contact with the first junction for the first cell 15. More specifically, the n-type conductivity gallium and nitride containing layer 20a of the first cell 15 is in direct contact with the p-type conductivity gallium and nitride containing layer 25b of the second cell 15.

In the embodiment depicted in FIG. 1, the second junction, i.e., p-n junction, of the second cell 10 is provided by a second p-type gallium nitride layer 25b and a second n-type gallium nitride layer 20b that are in direct contact with one another. These materials are one embodiment of a wide band gap material. The band gap for gallium nitride (GaN) is on the order of 3.4 eV. The second cell 10 of the photovoltaic device 100a that is depicted in FIG. 1 when receiving a light wavelength ranging from 300 nm to 400 nm can provide a voltage that is greater than 2.0 eV. In yet other examples, the voltage produced by the second cell 10 of the photovoltaic device 100a is greater than 2.25 eV. For example, the photovoltaic device 100a that includes the second cell 10 including the junction of the n-type gallium nitride (GaN) layer and the p-type gallium nitride (GaN) layer that is depicted in FIG. 1 may produce a voltage of 2.5 V or greater. It is noted that the above examples are provided for illustrative purposes only, and are not intended to limit the present disclosure. In other examples, the voltage produced by the second cell 10 of the photovoltaic device 100a composed of the n-type and p-type conductivity gallium nitride (GaN) layers depicted in FIG. 1 may be equal to 2.0 V, 2.25 V, 2.5 V, 2.75 V, 3.0 V, 3.25 V, and 3.5V, as well as any value between the aforementioned examples, and any range of voltages having a lower limit provided by one of the aforementioned example voltages, and an upper limit provided by one of the aforementioned example voltages.

Each of the second p-type conductivity gallium and nitride containing layer 25b, e.g., p-type gallium nitride (GaN), and the n-type conductivity gallium and nitride containing layer 20b, e.g., n-type gallium nitride (GaN) can have a thickness ranging from 500 nm to 2500 nm. In other embodiments, each of the second p-type conductivity gallium and nitride containing layer 25b, e.g., p-type gallium nitride (GaN), and the second n-type conductivity gallium and nitride containing layer 20b, e.g., n-type gallium nitride (GaN), can have a thickness ranging from 500 nm to 1500 nm. In one example, each of the second p-type conductivity gallium and nitride containing layer 25b and the first n-type conductivity gallium and nitride containing layer 20b have a thickness that is on the order of 0.5 microns, to provide a second cell 10 having a thickness on the order of 1 micron. In some embodiments, the thickness of the second p-type conductivity gallium and nitride containing layer 25b and the second n-type conductivity gallium and nitride containing layer 20b is selected to provide a second cell 10 having a thickness that is greater than the overlying first cell 15. For example, the thickness of the second p-type conductivity gallium and nitride containing layer 25b and the second n-type conductivity gallium and nitride containing layer 20b may be selected to provide a second cell 10 having a thickness of greater than 1.0 micron, when the first cell 15 has a thickness that is 0.5 microns or less.

The dopant that provides the n-type conductivity for the second n-type conductivity gallium and nitride containing layer 20b may be present in a concentration ranging from 10¹⁷ atoms/cm³ to 10²⁰ atoms/cm³. The dopant that provides the p-type conductivity of the second p-type conductivity gallium and nitride containing layer 25b may be present in a concentration ranging from 10¹⁷ atoms/cm³ to 10²⁰ atoms/cm³.

The photovoltaic device 100a that is depicted in FIG. 1 may be used for the generation of voltage from the application of a single wavelength of light. Prior examples of photovoltaic devices 100a include cells of junctions, i.e., p-n junctions, of different composition materials, in which the different compositions have different band gaps to absorb different wavelengths of light. In some embodiments, the photovoltaic devices described herein, such as the photovoltaic device including two cells, i.e., two p-n junctions of gallium nitride (GaN), as depicted in FIG. 1, uses a single wavelength of light, wherein in order to provide multiple voltage generating junctions, the stacked junctions have a lesser thickness the father the junction is positioned from the light source. This provides that the junctions, e.g., first junction 15, having the lesser thickness that are positioned closest to the light source absorb a first portion of the single wavelength light and at least a portion of a remaining single wavelength light is absorbed by at least at least a second cell 10 having a greater thickness, e.g., T2>T1, than the first cell 15.

The photovoltaic device 100a that is depicted in FIG. 1 produces voltage in response to a single wavelength on the order of 300 nm to 400 nm. In some embodiments, the photovoltaic device 100a that is depicted in FIG. 1 produces voltage in response to a single wavelength on the order of 325 nm to 375 nm. In one example, the photovoltaic device 100a that is depicted in FIG. 1 produces voltage in response to a single wavelength on the order of 350 nm.

The second cell 10 may be positioned on semiconductor substrate 5. In some embodiments, the semiconductor substrate 5 is composed of an n-type III-V semiconductor material, such as gallium nitride, e.g., n-type GaN. The photovoltaic devices 100a that are depicted in FIG. 1 may also include a glass substrate 4 on the light receiving end of the device. Contacts 21, 22 may be formed to the photovoltaic device 100a. Each of the contacts 21, 22 may be composed of an electrically conductive material, such as a metal, e.g., copper, tungsten, aluminum, tantalum, silver, platinum, gold and combinations and alloys thereof.

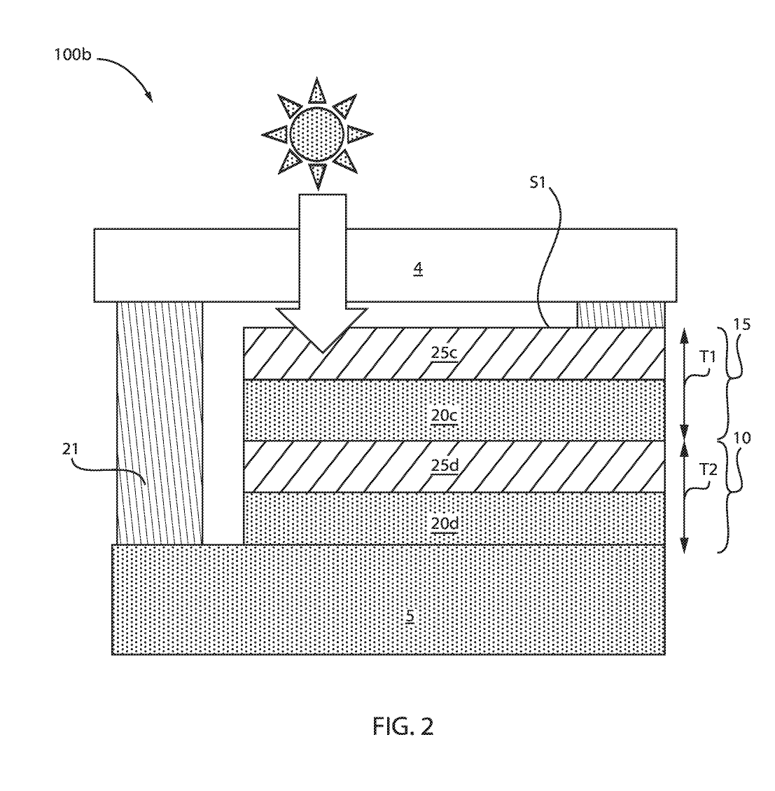

FIG. 2 depicts one embodiment of a high voltage photovoltaic cell 100b including two aluminum gallium nitride (AlGaN) junctions, i.e., two cells 15, 10, in which the first junction 25c, 20c closest to the light receiving end S1 of the device has a lesser thickness T1 than the junction 25d, 20d that is furthest from the light receiving end S1 of the device. Aluminum gallium nitride (AlGaN) is a wide bandgap material. The band gap for aluminum gallium nitride (AlGaN) is on the order of 4 eV. Although the photovoltaic device 100b that is depicted in FIG. 2 includes two cells 15, 10, the photovoltaic devices 100b that are provided in the present disclosure are not limited by only this example. For example, the number of cells in the material stack of aluminum gallium nitride (AlGaN) layers, i.e., number of cells including a junction, e.g., p-n junction, suitable for producing voltage in response to the application of light, may be equal to 2, 3, 4, 5, 10, 15, 20 and 25, or any range of cells having an upper level provided by one of the aforementioned examples, and a lower level provided by one of the aforementioned examples. In each of the above examples, the thickness of the junctions may be selected so that the thinnest junction cell is at the light receiving end S1 of the device, in which the thickness of the cells increase as the distance from the light receiving end S1 increases.

Each of the cells 15, 10 of the photovoltaic device 100b that is depicted in FIG. 2 when receiving a light wavelength ranging from 200 nm to 300 nm can provide a voltage that is greater than 2.5 V. In yet other examples, the voltage provided is greater than 3.0 V. For example, each of the cells 15, 10 of the photovoltaic device 100b that is depicted in FIG. 2 that is composed of a junction of n-type and p-type aluminum gallium nitride (AlGaN) layers may provide a voltage of 3.5 V or greater. It is noted that the prior examples are provided for illustrative purposes only, and are not intended to limit the present disclosure. In other examples, the voltage provided by each of the cells 10, 15 within the photovoltaic device 100b composed of a junction of n-type and p-type conductivity aluminum gallium nitride (AlGaN) may be equal to 2.5 V, 2.75 V, 3.0 V, 3.25 V and 3.5V, as well as any value between the aforementioned examples, and any range of voltages having a lower limit provided by one of the aforementioned examples, and an upper limit provided by one of the aforementioned examples.

Each of the first cell 15 and the second cell 10 include a junction, i.e., p-n junction, of aluminum gallium nitride (AlGaN) material layers. For example, the first cell 15 that is closest to the light receiving end has a first p-type aluminum gallium nitride (AlGaN) layer in direct contact with a first n-type aluminum gallium nitride (AlGaN) layer to provide a first p-n junction. The first n-type aluminum gallium nitride (AlGaN) 20c of the first cell 15 is in series connection, e.g., direct contact with, the second p-type aluminum gallium nitride layer 25d of the second cell 10. The second cell has a second p-type aluminum gallium nitride (AlGaN) layer 25d in direct contact with a first n-type aluminum gallium nitride (AlGaN) layer 20d to provide a second p-n junction. The dopant that provides the p-type conductivity of the n-type conductivity aluminum, gallium and nitride containing layers 25c, 25d may be present in a concentration ranging from 10¹⁷ atoms/cm³ to 10²⁰ atoms/cm³. The dopant that provides the n-type conductivity of the n-type conductivity aluminum, gallium and nitride containing layers 20c, 20d may be present in a concentration ranging from 10¹⁷ atoms/cm³ to 10²⁰ atoms/cm³.

For the first cell 15 that is closest to the light receiving end S1 of the photovoltaic device 100b, each of the p-type conductivity aluminum, gallium and nitrogen containing layer 25c, i.e., p-type aluminum, gallium nitride (AlGaN), and the n-type conductivity aluminum, gallium and nitrogen containing layer 20c, i.e., n-type aluminum gallium nitride (AlGaN), may have a thickness that is selected to provide a first cell 15 with a first thickness T1 that is less than the thickness, e.g., second thickness T2, of the cells, e.g., second cell 10, that are further from the light receiving end S1 of the photovoltaic device 100b than the first cell 15. For example, the thickness of each of the p-type conductivity aluminum, gallium and nitrogen containing layer 25c, and the n-type conductivity aluminum, gallium and nitrogen containing layer 20c may range from 100 nm to 2000 nm. In other embodiments, each of the p-type conductivity aluminum, gallium and nitride containing layer 25c, e.g., p-type gallium nitride (AlGaN), and the n-type conductivity aluminum, gallium and nitride containing layer 20c, e.g., n-type gallium nitride (AlGaN) can have a thickness ranging from 100 nm to 500 nm. Each of the second p-type conductivity aluminum gallium and nitride containing layer 25d, e.g., p-type aluminum gallium nitride (GaN), and the n-type conductivity aluminum, gallium and nitride containing layer 20d, e.g., n-type aluminum gallium nitride (AlGaN) can have a thickness ranging from 500 nm to 2500 nm. In other embodiments, each of the second p-type conductivity aluminum gallium and nitride containing layer 25d, e.g., p-type aluminum gallium nitride (AlGaN), and the second n-type conductivity aluminum gallium and nitride containing layer 20d, e.g., n-type aluminum gallium nitride (AlGaN), can have a thickness ranging from 500 nm to 1500 nm. In one example, each of the first p-type conductivity aluminum gallium and nitride containing layer 25c and the first n-type conductivity aluminum gallium and nitride containing layer 20c have a thickness that is on the order of 0.25 microns, to provide a first cell 15 having a thickness on the order of 0.5 microns; and each of the second p-type conductivity aluminum gallium and nitride containing layer 25d and the second n-type conductivity aluminum gallium and nitride containing layer 20d have a thickness that is on the order of 0.5 microns, to provide a second cell 10 having a thickness on the order of 1 micron.

The photovoltaic device 100b that is depicted in FIG. 2 may be positioned on semiconductor substrate 5. The semiconductor substrate 5 may be composed of an n-type III-V semiconductor material, such as aluminum gallium nitride, e.g., n-type AlGaN. The photovoltaic device 100b that is depicted in FIG. 2 may also include a glass substrate 4 on the light 3 receiving end of the device. The photovoltaic device 100b depicted in FIG. 2 also includes contacts 21, 22. These structures have been described above by the description of the structures having same reference numbers that are depicted in FIG. 1.

The photovoltaic device 100b that is depicted in FIG. 2 produces voltage in response to a single wavelength on the order of 200 nm to 300 nm. In some embodiments, the photovoltaic device 100b that is depicted in FIG. 2 produces voltage in response to a single wavelength on the order of 225 nm to 275 nm. In one example, the photovoltaic device 100b that is depicted in FIG. 2 produces voltage in response to a single wavelength on the order of 250 nm.

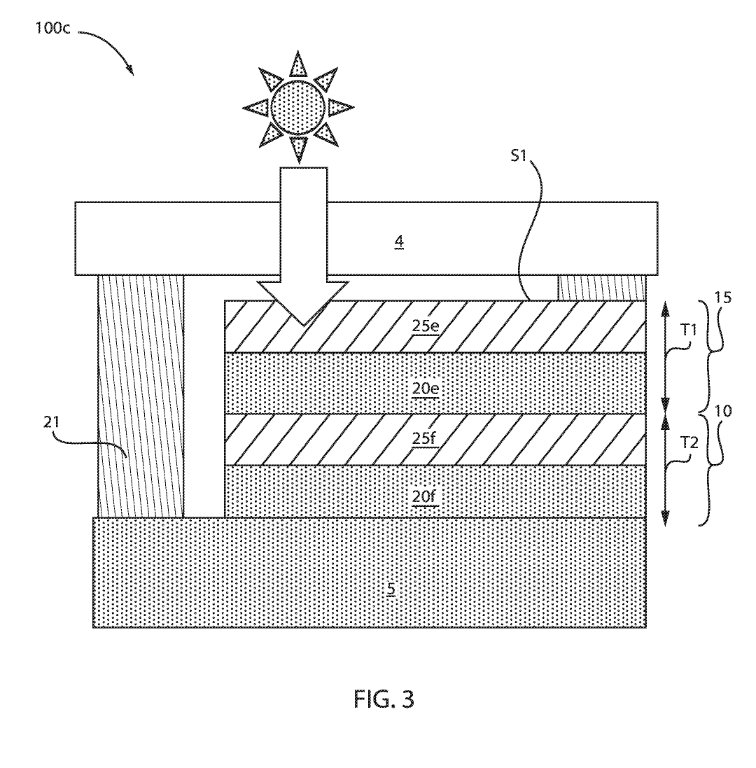

FIG. 3 depicts one embodiment of a high voltage photovoltaic device 100c including two aluminum nitride (AlN) junctions, i.e., a first cell 15 and a second cell 10 of aluminum nitride (AlN) junctions, in which the first junction, i.e., first cell 15, that is closest to the light receiving end S1 of the device has a lesser thickness T1 than the junction, e.g., second cell 10 having the second thickness T2, that is furthest from the light receiving end S1 of the device. Each of the cells 10, 15 are composed of aluminum nitride (AlN), which is a wide band gap material having a band gap ranging from 6.01 eV to 6.05 eV. Although the photovoltaic device 100c that is depicted in FIG. 3 includes two cells 15, 10, the photovoltaic devices 100c that are provided in the present disclosure are not limited by only this example. For example, the number of cells in the material stack of aluminum nitride (AlN) layers, i.e., number of cells including a junction, e.g., p-n junction, suitable for producing voltage in response to the application of light, may be equal to 2, 3, 4, 5, 10, 15, 20 and 25, or any range of cells having an upper level provided by one of the aforementioned examples, and a lower level provided by one of the aforementioned examples. In each of the above examples, the thickness of the junctions may be selected so that the thinnest junction cell is at the light receiving end S1 of the device, in which the thickness of the cells increase as the distance from the light receiving end 51 increases.

Each of the cells 15, 10 of the photovoltaic device 100c that are depicted in FIG. 3 when receiving a light wavelength ranging from 200 nm to 300 nm can provide a voltage that is greater than 2.5 V. In yet other examples, the voltage provided is greater than 3.0 V. For example, each of the cells 15, 10 of the photovoltaic device 100c that are depicted in FIG. 3 that are each composed of a junction of n-type and p-type aluminum nitride (AlN) layers may provide a voltage of 3.5 V or greater. It is noted that the prior examples are provided for illustrative purposes only, and are not intended to limit the present disclosure. In other examples, the voltage provided by each of the cells 10, 15 within the photovoltaic device 100c composed of a junction of n-type and p-type conductivity aluminum nitride (AlN) may be equal to 2.5 V, 2.75 V, 3.0 V, 3.25 V and 3.5V, as well as any value between the aforementioned examples, and any range of voltages having a lower limit provided by one of the aforementioned examples, and an upper limit provided by one of the aforementioned examples.

Each of the first cell 15 and the second cell 10 include a junction, i.e., p-n junction, of aluminum nitride (AlN) material layers 25e, 20e, 25f, 20f. For example, the first cell 15 that is closest to the light receiving end S1 has a first p-type aluminum nitride (AlN) layer 25e in direct contact with a first n-type aluminum nitride (AlN) layer 20e to provide a first p-n junction. The first n-type aluminum nitride (AlN) 20e of the first cell 15 is in series connection, e.g., direct contact with, the second p-type aluminum nitride layer 25f of the second cell 10. The second cell has a second p-type aluminum nitride (AlN) layer 25e in direct contact with a second n-type aluminum nitride (AlN) layer 20e to provide a second p-n junction. The dopant that provides the p-type conductivity of the n-type conductivity aluminum nitride containing layers 25e, 25f, 20e, 20f may be present in a concentration ranging from 10¹⁷ atoms/cm³ to 10²⁰ atoms/cm³.

For the first cell 15 that is closest to the light receiving end S1 of the photovoltaic device 100c, each of the p-type conductivity aluminum and nitrogen containing layer 25e, i.e., p-type aluminum nitride (AlN), and the n-type conductivity aluminum and nitrogen containing layer 20f, i.e., n-type aluminum nitride (AlN), may have a thickness that is selected to provide a first cell 15 with a first thickness T1 that is less than the thickness, e.g., second thickness T2, of the cells, e.g., second cell 10, that are further from the light receiving end S1 of the photovoltaic device 100b than the first cell 15. For example, the thickness of each of the first p-type conductivity aluminum and nitrogen containing layer 25e, e.g., aluminum nitride (AlN), and the first n-type conductivity aluminum and nitrogen containing layer 20e, e.g., aluminum nitride (AlN) may range from 100 nm to 2000 nm. In other embodiments, each of the first p-type conductivity aluminum and nitrogen containing layer 25e, e.g., p-type aluminum nitride (AlN), and the first n-type conductivity aluminum and nitrogen containing layer 20e, e.g., n-type aluminum nitride (AlN) can have a thickness ranging from 100 nm to 500 nm. Each of the second p-type conductivity aluminum and nitrogen containing layers 25f, e.g., p-type aluminum gallium nitride (GaN), and the second n-type conductivity aluminum and nitrogen containing layer 20f, e.g., n-type aluminum nitride (AlN) can have a thickness ranging from 500 nm to 2500 nm. In other embodiments, each of the second p-type conductivity aluminum and nitrogen containing layer 25f, e.g., p-type aluminum gallium nitride (AlN), and the second n-type conductivity aluminum and nitrogen containing layer 20f, e.g., n-type aluminum nitride (AlN), can have a thickness ranging from 500 nm to 1500 nm.

In one example, each of the first p-type conductivity aluminum and nitrogen containing layers 25e and the first n-type conductivity aluminum and nitrogen containing layer 20e have a thickness that is on the order of 0.25 microns, to provide a first cell 15 having a thickness on the order of 0.5 microns; and each of the second p-type conductivity aluminum and nitrogen containing layer 25f and the second n-type conductivity aluminum and nitrogen containing layer 20f have a thickness that is on the order of 0.5 microns, to provide a second cell 10 having a thickness on the order of 1 micron.

The photovoltaic device 100c that is depicted in FIG. 3 may be positioned on semiconductor substrate 5. The semiconductor substrate 5 may be composed of an n-type III-V semiconductor material, such as aluminum nitride, e.g., n-type AlN. The photovoltaic device 100c that is depicted in FIG. 3 may also include a glass substrate 4 on the light 3 receiving end of the device. The photovoltaic device 100c depicted in FIG. 3 also includes contacts 21, 22. These structures have been described above by the description of the structures having same reference numbers that are depicted in FIG. 1.

The photovoltaic device 100c that is depicted in FIG. 3 produces voltage in response to a single wavelength on the order of 150 nm to 250 nm. In some embodiments, the photovoltaic device 100c that is depicted in FIG. 3 produces voltage in response to a single wavelength on the order of 175 nm to 225 nm. In one example, the photovoltaic device 100c that is depicted in FIG. 3 produces voltage in response to a single wavelength on the order of 200 nm.

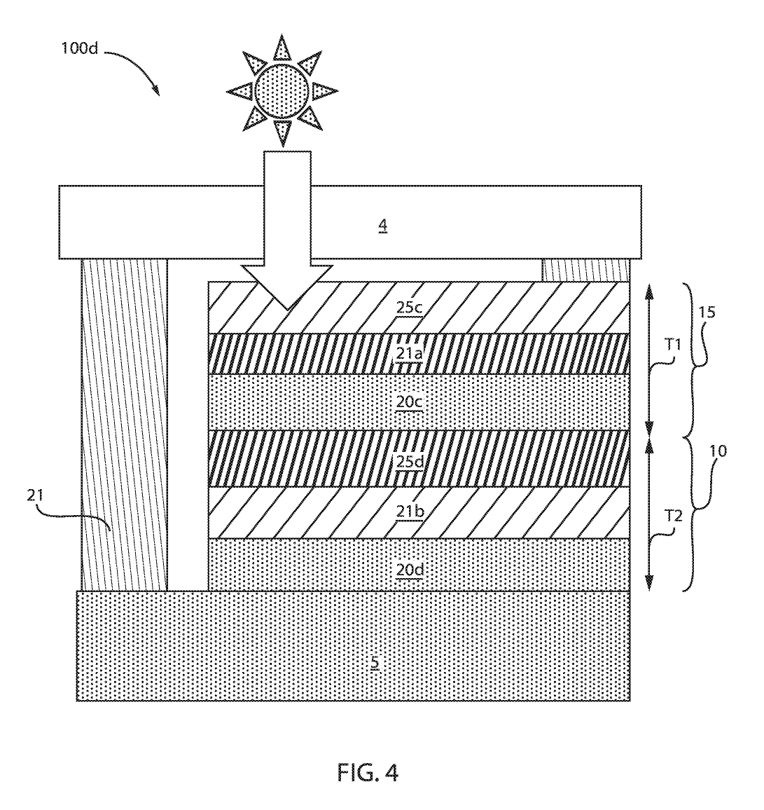

FIG. 4 depicts one embodiment of a high voltage photovoltaic device 100d including junctions of p-type aluminum gallium nitride (p-AlGaN) 25c, 25d, intrinsic gallium nitride (i-GaN) 21a, 21b and n-type aluminum gallium nitride (n-AlGaN) 20c, 20d, in which the first junction, i.e., first cell 15, closest to the light receiving end S1 of the device has a lesser thickness than the junction, i.e., second cell 20, that is furthest from the light receiving end of the device 100d. The first and second cell 15, 10 depicted in FIG. 4 are P-I-N junctions, which in include a p-type conductivity layer, i.e., p-type aluminum gallium nitride (p-AlGaN) 25c, 25d, that is in direct contact with an intrinsic semiconductor, i.e., intrinsic gallium nitride (i-GaN) 21a, 21b, wherein an n-type conductivity layer, such as n-type aluminum gallium nitride (n-AlGaN) 20c, 20d is in direct contact with an opposing side of the intrinsic semiconductor to provide that the intrinsic semiconductor is positioned between the p-type and n-type conductivity semiconductor layers.

The p-type aluminum gallium nitride (p-AlGaN) 25c, 25d, and the n-type aluminum gallium nitride (n-AlGaN) 20c, 20d that are depicted in FIG. 4 are similar to the p-type aluminum gallium nitride (p-AlGaN) 25c, 25d, and the n-type aluminum gallium nitride (n-AlGaN) 20c, 20d that are depicted in FIG. 2. Therefore, the description of the p-type aluminum gallium nitride (p-AlGaN) 25c, 25d, and the n-type aluminum gallium nitride (n-AlGaN) 20c, 20d from FIG. 2 is suitable for describing one example of the p-type aluminum gallium nitride (p-AlGaN) 25c, 25d, and the n-type aluminum gallium nitride (n-AlGaN) 20c, 20d that are depcited in FIG. 4 with the exception that the thicknesses of the p-type aluminum gallium nitride (p-AlGaN) 25c, 25d, and the n-type aluminum gallium nitride (n-AlGaN) 20c, 20d depicted in FIG. 4 may be adjusted to account for the intrinsic gallium nitride layer 21a, 21b. The term “intrinsic” as used to describe the intrinsic gallium nitride layer 21a, 21b means that these material layers are not extrinsically doped, e.g., by ion implantation or insitu doping, with n-type or p-type dopant. The number of charge carriers is therefore determined by the properties of the material itself instead of the amount of impurities. With the exception of being free of extrinsically added n-type or p-type dopant, the intrinsic gallium nitride layer 21a, 21b is similar to the gallium nitride containing layers 25a, 20a, 25b, 20b that are depicted in FIG. 1. Therefore, the description of the gallium nitride containing layers 25a, 20a, 25b, 20b from FIG. 1 is suitable for describing one example of the p-type aluminum gallium nitride (p-AlGaN) 25c, 25d, and the intrinsic gallium nitride layer 21a, 21b that are depcited in FIG. 4 with the exception that the thicknesses of the intrinsic gallium nitride layer 21a, 21b.

The thickness of the aforementioned p-type conductivity aluminum gallium nitride layers 25c, 25d, the intrinsic gallium nitride layer 21a, 21b, and the n-type conductivity aluminum gallium nitride layers 20c, 20d, are selected so that the P-I-N junction of the first cell 15 has a lesser thickness than the P-I-N junction of the second cell 10. Further, similar to the previous embodiments, each P-I-N junction is composed of similar material composition layers in a same sequence, so that each cell 15, 10 produces voltage in response to a single wavelength of light. By modulating the thickness of the cells 15, 10, so that the cells closest to the light receiving end S1 of the photovoltaic device 100d have a lesser thickness and that the cells layered in a direction away from the light receiving end S1 have a greater thickness with increases distance from the light receiving end; the cells 15 that are closest to the light receiving end S1 absorb a first portion of light to produce a first voltage, and the cells further from the light receiving end S1 absorb a portion of the remaining light to produce a second voltage, etc.

For example, the thickness of each of the p-type conductivity aluminum gallium and nitrogen containing layers 25c, 25d, e.g., p-type aluminum gallium nitride (AlGaN), each intrinsic layer, e.g., intrinsic gallium nitride (i-GaN) 21a, 21b, and each of the n-type conductivity aluminum, gallium and nitrogen containing layers 20c, 20d, e.g., aluminum gallium nitride (AlGaN) may have a thickness ranging from 100 nm to 2000 nm.

In one example, the thickness of the p-type conductivity aluminum gallium and nitrogen containing layer 25c, the intrinsic gallium nitride (i-GaN) 21a, and the n-type conductivity aluminum, gallium and nitrogen containing layers 20c are selected to provide a first cell 15 having a thickness on the order of 0.5 microns; and the thickness each of the p-type conductivity aluminum gallium and nitrogen containing layer 25d, the intrinsic gallium nitride (i-GaN) 21b, and the n-type conductivity aluminum, gallium and nitrogen containing layers 20d is selected to provide a second cell 10 having a thickness on the order of 1 micron.

The photovoltaic device 100d that is depicted in FIG. 4 may be positioned on semiconductor substrate 5. The semiconductor substrate 5 may be composed of an n-type III-V semiconductor material, such as aluminum gallium nitride, e.g., n-type AlGaN. The photovoltaic device 100d that is depicted in FIG. 4 may also include a glass substrate 4 on the light 3 receiving end of the device. The photovoltaic device 100d depicted in FIG. 4 also includes contacts 21, 22.

The photovoltaic device 100d that is depicted in FIG. 4 produces voltage in response to a single wavelength on the order of 300 nm to 400 nm. In some embodiments, the photovoltaic device 100d that is depicted in FIG. 4 produces voltage in response to a single wavelength on the order of 325 nm to 375 nm. In one example, the photovoltaic device 100d that is depicted in FIG. 4 produces voltage in response to a single wavelength on the order of 350 nm.

Each of the cells 15, 10 of the photovoltaic device 100d that are depicted in FIG. 4 when receiving a light wavelength in the aforementioned range can provide a voltage that is greater than 2.5 V. In yet other examples, the voltage provided is greater than 3.0 V. For example, each of the cells 15, 10 of the photovoltaic device 100d that are depicted in FIG. 4 may provide a voltage of 3.5 V or greater. It is noted that the prior examples are provided for illustrative purposes only, and are not intended to limit the present disclosure. In other examples, the voltage provided by each of the cells 10, 15 within the photovoltaic device 100d depicted in FIG. 4 may be equal to 2.5 V, 2.75 V, 3.0 V, 3.25 V and 3.5V, as well as any value between the aforementioned examples, and any range of voltages having a lower limit provided by one of the aforementioned examples, and an upper limit provided by one of the aforementioned examples.

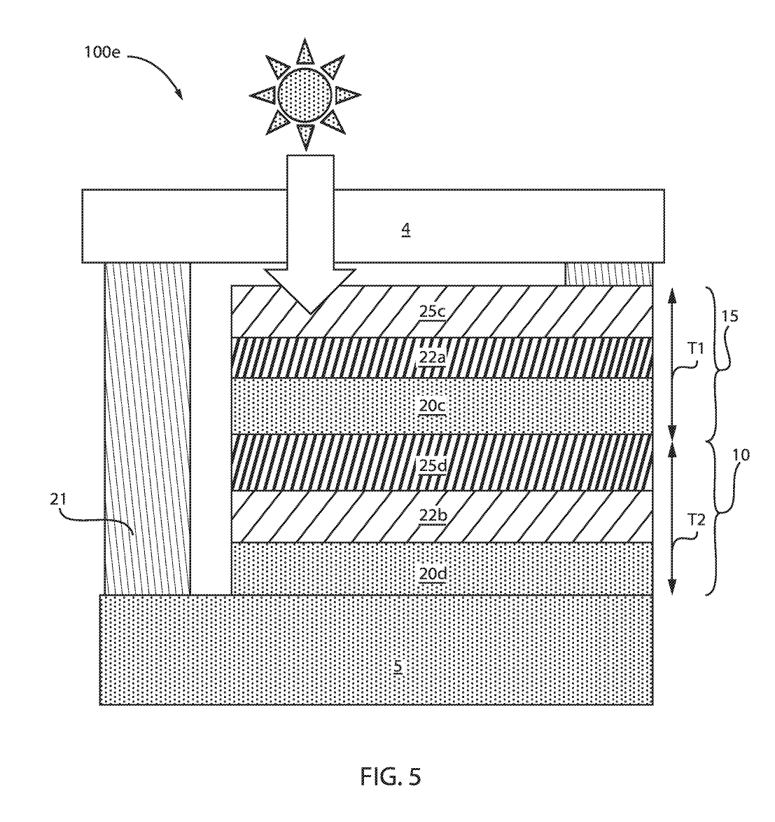

FIG. 5 depicts one embodiment of a high voltage photovoltaic cell 100e including junctions 10, 15 of p-type aluminum gallium nitride (p-AlGaN), intrinsic indium gallium nitride (i-InGaN) and gallium nitride (GaN) quantum wells and n-type aluminum gallium nitride (n-GaN), in which the first junction closest to the light receiving end of the device has a lesser thickness than the junction that is furthest from the light receiving end S1 of the device.

The first and second cell 15, 10 depicted in FIG. 5 include quantum wells 22a, 22b positioned between the n-type and p-type conductivity layers of the junction for each cell. In the embodiment depicted in FIG. 5, the p-type conductivity layers of the junctions are provided by aluminum gallium nitride and the n-type conductivity layers of the junctions are provided by aluminum gallium nitride.

The p-type aluminum gallium nitride (p-AlGaN) 25c, 25d, and the n-type aluminum gallium nitride (n-AlGaN) 20c, 20d that are depicted in FIG. 4 are similar to the p-type aluminum gallium nitride (p-AlGaN) 25c, 25d, and the n-type aluminum gallium nitride (n-AlGaN) 20c, 20d that are depicted in FIG. 2. Therefore, the description of the p-type aluminum gallium nitride (p-AlGaN) 25c, 25d, and the n-type aluminum gallium nitride (n-AlGaN) 20c, 20d from FIG. 2 is suitable for describing one example of the p-type aluminum gallium nitride (p-AlGaN) 25c, 25d, and the n-type aluminum gallium nitride (n-AlGaN) 20c, 20d that are depcited in FIG. 5 with the exception that the thicknesses of the p-type aluminum gallium nitride (p-AlGaN) 25c, 25d, and the n-type aluminum gallium nitride (n-AlGaN) 20c, 20d depicted in FIG. 5 may be adjusted to account for the quantum wells 22a, 22b.

The quantum wells 22a, 22b depicted in FIG. 5 include intrinsic layer of indium gallium nitride (InGaN) and gallium nitride (GaN) Indium gallium nitride (InGaN) has a band gap of approximately 2.7 eV, while gallium nitride (GaN) has a band gap of approximately 3.4 eV. To provide the stacked structure of quantum wells, the thickness of each layer of semiconductor material within the quantum well may be no greater than 50 nm. For example, the thickness for each layer of the III-V compound semiconductor material, e.g., gallium (GaN) and/or indium gallium nitride (InGaN), within the quantum wells 22a, 22b may range from 5 nm to 10 nm. In some embodiments, the stacked structure of quantum wells may be composed of 1 to 100 layers of semiconductor material, such as III-V compound semiconductor materials, e.g., the high band gap GaN and/or low band gap InGaN. In yet another embodiment, the stacked structure of quantum wells 22a, 22b may be composed of 1 to 5 layers of semiconductor material layers.

The thickness of the aforementioned p-type conductivity aluminum gallium nitride layers 25c, 25d, the quantum wells 22a, 22b, and the n-type conductivity aluminum gallium nitride layers 20c, 20d, are selected so that the first cell 15 has a lesser thickness than the second cell 10. Further, similar to the previous embodiments, each junction is composed of similar material composition layers in a same sequence, so that each cell 15, 10 produces voltage in response to a single wavelength of light. By modulating the thickness of the cells 15, 10, so that the cells closest to the light receiving end S1 of the photovoltaic device 100e have a lesser thickness and that the cells layered in a direction away from the light receiving end S1 have a greater thickness with increases distance from the light receiving end; the cells 15 that are closest to the light receiving end S1 absorb a first portion of light to produce a first voltage, and the cells further from the light receiving end S1 absorb a portion of the remaining light to produce a second voltage, etc.

For example, the thickness of each of the p-type conductivity aluminum gallium and nitrogen containing layers 25c, 25d, e.g., p-type aluminum gallium nitride (AlGaN), each quantum well 22a, 22b, and each of the n-type conductivity aluminum, gallium and nitrogen containing layers 20c, 20d, e.g., aluminum gallium nitride (AlGaN) may have a thickness ranging from 100 nm to 2000 nm.

In one example, the thickness of the p-type conductivity aluminum gallium and nitrogen containing layer 25c, the first quantum well 22a, and the n-type conductivity aluminum, gallium and nitrogen containing layers 20c are selected to provide a first cell 15 having a thickness on the order of 0.5 microns; and the thickness each of the p-type conductivity aluminum gallium and nitrogen containing layer 25d, the second quantum well 22b, and the n-type conductivity aluminum, gallium and nitrogen containing layers 20d is selected to provide a second cell 10 having a thickness on the order of 1 micron.

The photovoltaic device 100e that is depicted in FIG. 5 may be positioned on semiconductor substrate 5. The semiconductor substrate 5 can be composed of an n-type III-V semiconductor material, such as aluminum gallium nitride, e.g., n-type AlGaN. The photovoltaic device 100e that is depicted in FIG. 5 may also include a glass substrate 4 on the light 3 receiving end of the device. The photovoltaic device 100e depicted in FIG. 5 also includes contacts 21, 22.

The photovoltaic device 100e that is depicted in FIG. 5 produces voltage in response to a single wavelength on the order of 400 nm to 500 nm. In some embodiments, the photovoltaic device 100e that is depicted in FIG. 5 produces voltage in response to a single wavelength on the order of 425 nm to 475 nm. In one example, the photovoltaic device 100e that is depicted in FIG. 5 produces voltage in response to a single wavelength on the order of 450 nm.

Each of the cells 15, 10 of the photovoltaic device 100e that are depicted in FIG. 5 when receiving a light wavelength in the aforementioned range can provide a voltage that is greater than 2.5 V. In yet other examples, the voltage provided is greater than 3.0 V. For example, each of the cells 15, 10 of the photovoltaic device 100e that are depicted in FIG. 5 may provide a voltage of 3.5 V or greater. It is noted that the prior examples are provided for illustrative purposes only, and are not intended to limit the present disclosure. In other examples, the voltage provided by each of the cells 10, 15 within the photovoltaic device 100d depicted in FIG. 5 may be equal to 2.5 V, 2.75 V, 3.0 V, 3.25 V and 3.5V, as well as any value between the aforementioned examples, and any range of voltages having a lower limit provided by one of the aforementioned examples, and an upper limit provided by one of the aforementioned examples.

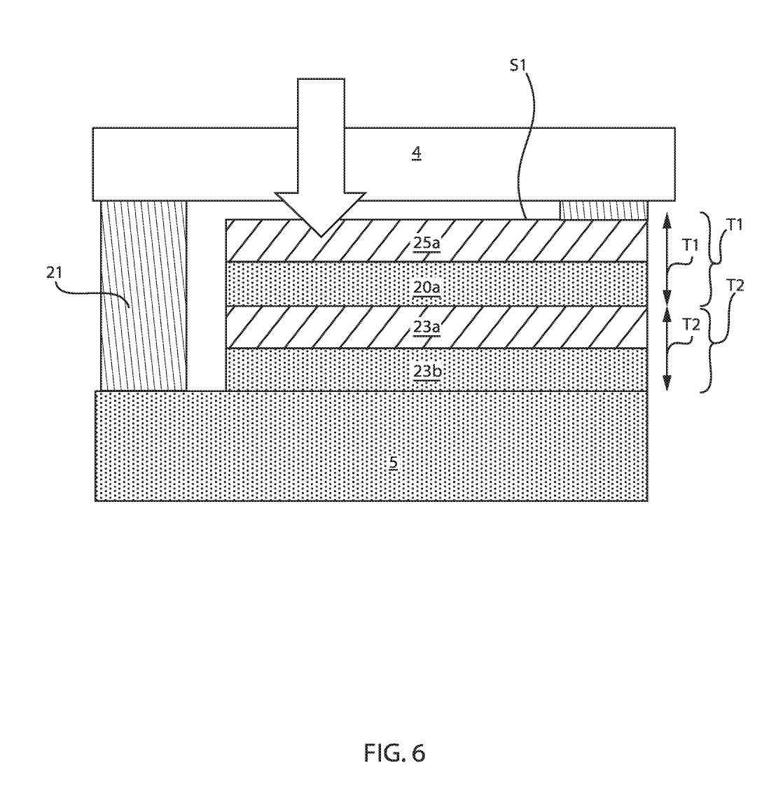

FIG. 6 depicts one embodiment of a photovoltaic cell 100f including a first junction 15 of p-type gallium nitride 25a and n-type gallium nitride 20a, and a second junction 10 of p-type silicon carbide 23a and n-type silicon carbide 23b, in which the first junction closest to the light receiving end S1 of the device has a lesser thickness T1 than the junction that is furthest from the light receiving end of the device. The photovoltaic device depicted in FIG. 6 is similar to the devices depicted in FIGS. 1-4 with the exception that the two junctions are composed of different composition materials. But, in the embodiment depicted in FIG. 6, the band gap of the materials of the first cell 15, e.g., gallium nitride, can be substantially equal to the band gap of the materials in the second cell 10, e.g., silicon carbide. For example, the band gap for gallium nitride (GaN) is on the order of 3.4 eV; while the band gap for silicon carbide (SiC) may range from 2.3 eV to 3.05 eV depending on the poly type. In some embodiments, the band gap of silicon carbide (SiC) may be equal to the band gap of gallium nitride (GaN).

The photovoltaic devices 100a, 100b, 100c, 100d, 100e, 100f depicted in FIGS. 1-6 may be formed by a method including a low hydrogen deposition process. The term “low hydrogen” denotes that the deposition step has a maximum hydrogen content of 1×10¹⁸ cm⁻³. In some embodiments, the method may include growing a bottom cell 10 on a supporting substrate 5, in which the bottom cell 10 includes a bottom sequence of material compositions to provide a bottom junction; and forming at least one upper cell 15 on the bottom junction by a deposition method using low hydrogen precursors. The upper cell 15 includes an upper sequence of material compositions to provide an upper junction, in which the upper sequence of the material compositions is substantially a same sequence of composition material layers as the bottom sequence of material compositions. The upper cell 15 has a lesser thickness T1 than the thickness T2 of bottom cell 10. The upper cell 15 is positioned at the light receiving end S1 of the photovoltaic device.

The method may begin with forming lower junction, i.e., bottom cell 10, by metal organic chemical vapor deposition (MOCVD) or molecular beam epitaxy (MBE). The lower junction may be formed on a supporting substrate 5. The material layers of the lower junction, i.e., bottom cell 10, may be formed using epitaxial growth. The terms “epitaxial growth and/or deposition” means the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation. The epitaxial growth process may be by chemical vapor deposition (CVD) or molecular beam epitaxy (MBE) growth processes.

MBE growth processes can include heat the substrate, e.g., with a temperature ranging from 500-600° C. In a following step, MBE growth processes include a precise beam of atoms or molecules (heated up so they're in gas form) being fired at the substrate from “guns” called effusion cells. The composition of the molecules being fired in the beams provide the composition of the deposited material layer. The molecules land on the surface of the substrate, condense, and build up systematically in ultra-thin layers, so that the material layer being grown forms one atomic layer at a time.

Chemical vapor deposition (CVD) is a deposition process in which a deposited species is formed as a result of chemical reaction between gaseous reactants at greater than room temperature (25° C. to 900° C.); wherein solid product of the reaction is deposited on the surface on which a film, coating, or layer of the solid product is to be formed. Variations of CVD processes include, but not limited to, Atmospheric Pressure CVD (APCVD), Low Pressure CVD (LPCVD) and Plasma Enhanced CVD (PECVD), Metal-Organic CVD (MOCVD) and combinations thereof may also be employed. In some preferred embodiments, the CVD process used to form the lower junction may be metal organic chemical vapor deposition.

A number of different sources may be used for the deposition of epitaxial type III-V semiconductor material. In some embodiments, the sources for epitaxial growth of type III-V semiconductor material include solid sources containing In, Ga, N, P elements and combinations thereof and/or a gas precursor selected from the group consisting of trimethylgallium (TMG), trimethylindium (TMI), Trimethylaluminum (TMA), tertiary-butylphosphine (TBP), phosphine (PH₃), ammonia (NH₃), and combinations thereof.

The material layers for the lower junction may be doped n-type or p-type using in situ doping. By “in-situ” it is meant that the dopant that provides the conductivity type of the material layer, e.g., material layer that contributes to providing a junction, is introduced as the material layer is being formed. To provide for in-situ doped p-type or n-type conductivity, the dopant gas may be selected from the group consisting of bis-cyclopentadienyl-magnesium (Cp₂Mg), silane (SiH₄), disilane (Si₂H₆), germane (GeH₄), carbon tetrabromide (CBr₄) and combinations thereof. The intrinsic materials of the quantum wells and the PIN junctions are not doped with n-type or p-type dopant. The dopants within the first junction are activated following the formation of the bottom cell 10. Activation anneal may be conducted at a temperature ranging from 850° C. to 1350° C. Activation annealing may be provided by furnace annealing, rapid thermal annealing (RTA) or laser annealing.

In some embodiments, the method continues by forming the upper junction, i.e., upper cell 15, using a low hydrogen deposition process, such as MBE. It has been determined that hydrogen precursors can deactivate the electrically activated p-type dopant in the underlying p-type gallium nitride containing layers and/or p-type aluminum gallium containing nitride layers. Therefore, the method for depositing the material layers of the upper cell 15 can employ a low-hydrogen containing process, e.g., deposition method using hydrogen free precursors, such as MBE. A second activation anneal may be formed after the formation of the upper junction that is similar to the above described first activation anneal. Photolithography and etch processes can provide the geometry for the photovoltaic device 100a, 100b, 100c, 100d, 100e. Thereafter, the contacts 21, 22 may be formed to the photovoltaic device 100a, 100b, 100c, 100d, 100e using deposition, photolithography and etching processes.

Having described preferred embodiments of a system and method (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A photovoltaic device comprising:
a first cell positioned at a light receiving end of the photovoltaic device, the first cell comprising first junction having a first sequence of first semiconductor material layers, the first cell having a first thickness; and
at least a second cell positioned further from the light receiving end of the photovoltaic device than the first cell, wherein each cell said at least the second cell has greater thickness than the first thickness, said at least second cell comprising a second junction having second semiconductor material layers in a second sequence equal to the first sequence of first semiconductor material layers in said first junction.

2. The photovoltaic device of claim 1, wherein the second cell has a thickness at least twice the first cell.

3. The photovoltaic device of claim 1, wherein the first junction is provided by a first p-type gallium nitride layer and a first n-type gallium nitride layer, and said second junction in direct contact with the first junction, the second junction comprising a second p-type gallium nitride layer and a second n-type gallium nitride layer, wherein the photovoltaic device produces voltage in response to light wavelengths ranging from 300 nm to 400 nm.

4. The photovoltaic device of claim 1, wherein the first junction comprises a first p-type aluminum gallium nitride layer and a first n-type aluminum gallium nitride layer, and said second junction is in direct contact with the first junction, the second junction comprising a second p-type aluminum gallium nitride layer and a second n-type aluminum gallium nitride layer, wherein the photovoltaic device produces voltage in response to light wavelengths ranging from 200 nm to 300 nm.

5. The photovoltaic device of claim 1, wherein the first junction comprises a first p-type aluminum nitride layer and a first n-type aluminum nitride layer, and said second junction is in direct contact with the first junction, the second junction comprising a second p-type aluminum nitride layer and a second n-type aluminum nitride layer, wherein the photovoltaic device produces voltage in response to light wavelengths ranging from 150 nm to 250 nm.

6. The photovoltaic device of claim 1, wherein the first junction comprises a first p-type aluminum gallium nitride layer, a first intrinsic gallium nitride layer, and a first n-type aluminum gallium nitride layer, and the second junction comprises a second junction in direct contact with the first junction, the second junction comprising a second p-type aluminum gallium nitride layer, a second intrinsic gallium nitride layer and a second n-type aluminum gallium nitride layer, wherein the photovoltaic device produces voltage in response to light wavelengths ranging from 300 nm to 400 nm.

7. The photovoltaic device of claim 1, wherein the first junction comprises a first p-type aluminum gallium nitride layer, a first multi-quantum well of indium gallium nitride and gallium nitride, and a first n-type aluminum gallium nitride layer, and said second junction is direct contact with the first junction, the second junction comprising a second p-type aluminum gallium nitride layer, a second multi-quantum well of indium gallium nitride and gallium nitride, and a second n-type aluminum gallium nitride layer, wherein the photovoltaic device produces voltage in response to light wavelengths ranging from 300 nm to 400 nm.

8. The photovoltaic device of claim 1, wherein the first junction comprises a first p-type gallium nitride layer and a first n-type gallium nitride layer, and said at least said second cell comprises a second junction in direct contact with the first junction, the second junction comprises a second p-type silicon carbide layer and a second n-type silicon carbide layer, wherein the photovoltaic device produces voltage in response to light wavelengths ranging from 300 nm to 400 nm.

9.-20. (canceled)
